(19) United States
(12) Patent Application Publication
(10) Pub. No.: US 2025/0189636 A1
(43) Pub. Date: Jun. 12, 2025

(54) LIGHT SENSOR

(71) Applicant: SENSORTEK TECHNOLOGY CORP., Hsinchu County (TW)

(72) Inventors: Yu-Min Lin, Hsinchu County (TW); Ching-Kuan Chiu, Hsinchu County (TW)

(21) Appl. No.: 18/925,093

(22) Filed: Oct. 24, 2024

Related U.S. Application Data
(60) Provisional application No. 63/545,374, filed on Oct. 24, 2023.

(51) Int. Cl. G01S 7/481; G01S 17/08

(52) U.S. Cl. CPC G01S 7/4816; G01S 17/08

(57) ABSTRACT

A light sensor comprises a light-emitting component and a light-receiving component. The light-emitting component is configured to emit a light signal. The light-receiving component includes a light sensing layer and an interlayer disposed on the light sensing layer along a vertical direction. Multiple microstructures are disposed on a surface of the light sensing layer facing the interlayer. A portion of the light signal reflected by an object enters the light-receiving component and is received by the light sensing layer after passing through the interlayer. Thereby, the light sensor reduces non-uniform light transmittance phenomenon and lowers production costs of the light sensor.

### FIELD OF THE INVENTION

The present application relates to a light sensor, particularly to a light sensor comprising a light emitting component and a light receiving component.

### BACKGROUND OF THE INVENTION

Light sensors implemented through light sensing technology are widely used in many applications, for example, a proximity sensor may be used to detect the distance between an object and electronic devices (such as smartphones, wireless Bluetooth earphones, etc.). Consequently, when the proximity sensor is close to the user's face, the phone may turn off the display screen and disable touch functions to prevent a phone call from interrupting the conversation by the user's face accidental touching; or, when the proximity sensor is taken away from the user's ear, the earphones may also turn off the audio playback function to save energy consumption.

Please refer to FIG. 1, generally, conventional light sensors 9 used as proximity sensors typically is equipped with a light-emitting diode (LED) or a laser diode as the light emitting component 91 to emit light, and when the light is emitted toward a nearby object A, the reflected light intensity is sensed by the light receiving component 92 to determine the distance to the object. It should be noted that when the light reflected by the nearby object A enters the light receiving component 92 at different incident angles, a ripple in transmittance occurs.

Specifically, please refer to FIG. 2, which shows the transmittance of light sensor 9 when sensing light entered at different incident angles. The transmittance is the sensing efficiency of light transmitted from air into light sensor 9 and being sensed by a light sensing layer 921. If the incident angles of two light rays L1 and L2 are θ1 and θ2, which are 10° and 20° respectively, the figure shows a significant difference in transmittances of both, which is the mentioned ripple in transmittance.

Although attempts may be made to solve the uneven transmittance of light at different incident angles through circuit compensation, the issues in practices are the products in mass production influenced by process variations, wherein each light sensor 9 may exhibit different transmittance distributions. For instance, refer to FIG. 3, for two samples S1 and S2 of light sensor 9, distinctly different transmittance distributions may be formed, wherein one sample, S1, has a transmittance at the peak of ripple in transmittance while the incident angle is 0°; however, another sample, S2, has a transmittance at the valley of ripple in transmittance at the same incident angle. This results in significant optical performance variations among products of mass production, leading to difficulties in product calibration or poor yield rates, severely increasing the production costs of light sensors.

In light of above, there is indeed a need to improve conventional light sensors, thereby enabling electronic devices to achieve more precise or diverse control functions with lower costs.

### SUMMARY OF THE INVENTION

An objective of the present application is to provide a light sensor and its control method, which involves placing a plurality of microstructures in the light sensing layer of the light receiving component to change the direction of light passing through the layers of the light emitting component, thereby avoiding constructive or destructive interference. This allows for the reduction of ripple in transmittance when light emitted by the light emitting component enters the light receiving component at different incident angles after being reflected by an object, effectively limiting optical performance variations among light sensor products, addressing issues of product calibration difficulty or poor yield rates, and significantly reducing the production costs of light sensors.

The present application relates to a light sensor, comprising a light emitting component and a light receiving component. The light emitting component emits a light signal. The light receiving component includes a light sensing layer and an interlayer, with the interlayer disposed vertically above the light sensing layer. A plurality of microstructures are placed on the surface of the light sensing layer facing the interlayer. The part of the light signal that is reflected by an object enters the light receiving component and is received by the light sensing layer after passing through the interlayer.

### BRIEF DESCRIPTION OF DRAWINGS

FIG. 1 which is a schematic diagram of the structure of a conventional light sensor;

FIG. 2 which is a schematic diagram of the transmittance when a sample of the light sensor senses light at different incident angles;

FIG. 3 which is a schematic diagram of the transmittance distribution of two samples of the conventional light sensor;

FIG. 4 which is a schematic diagram of the structure of the light sensor in the first embodiment of the present application;

FIG. 5A which is an enlarged schematic diagram of the rectangular cross-sectional microstructure of the light sensor in the first embodiment of the present application;

FIG. 5B which is an enlarged schematic diagram of the arc-shaped cross-sectional microstructure of the light sensor in the first embodiment of the present application;

FIG. 5C which is an enlarged schematic diagram of the triangular cross-sectional microstructure of the light sensor in the first embodiment of the present application;

FIG. 5D which is an enlarged schematic diagram of the trapezoidal cross-sectional microstructure of the light sensor in the first embodiment of the present application;

FIG. 5E which is an enlarged schematic diagram of the light sensor in the first embodiment of the present application, featuring more than two types of microstructures;

FIG. 6 which is a schematic diagram of the transmittance distribution of two samples of the light sensor in the first embodiment;

FIG. 7 which is a schematic diagram of the structure of the light sensor in the second embodiment of the present application; and

FIG. 8 which is a schematic diagram of the structure of the light sensor in the third embodiment of the present application.

### DETAILED DESCRIPTION OF THE INVENTION

Certain terms are used in the specification and claims to refer to particular components; however, those skilled in the art should understand that manufacturers may use different terms to refer to the same component, and moreover, the specification and claims do not distinguish components based on the difference in terms, but rather on the differences in the components in terms of overall technology.

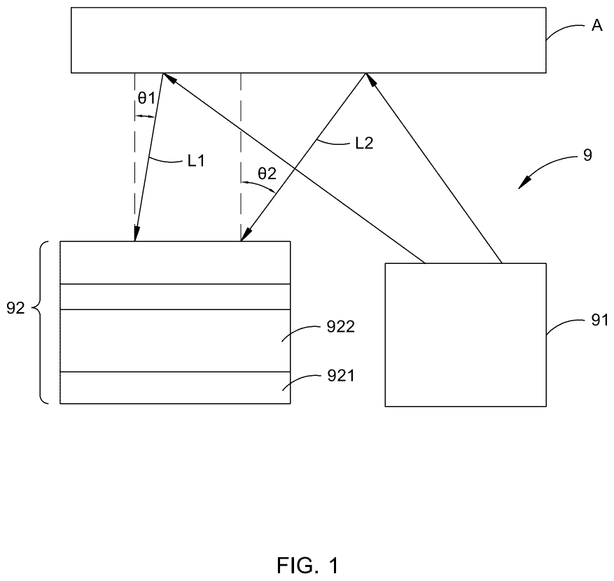

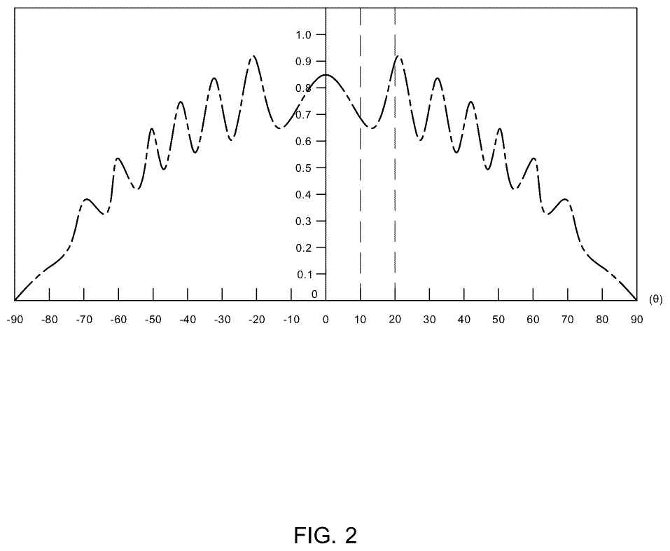

To further illustrate the improvements made by the present application, please refer to FIG. 1 as shown. Upon investigation by the inventor, the uneven transmittance of light entering the light receiving component 92 at different incident angles is primarily due to the difference in refractive index between the light sensing layer 921 of the light receiving component 92 and an adjacent interlayer 922; Additionally, the thickness required for this interlayer 922 in practical applications is substantial (usually >6 um), sufficient to meet the conditions for constructive or destructive interference, thereby causing ripple in transmittance for light at different incident angles.

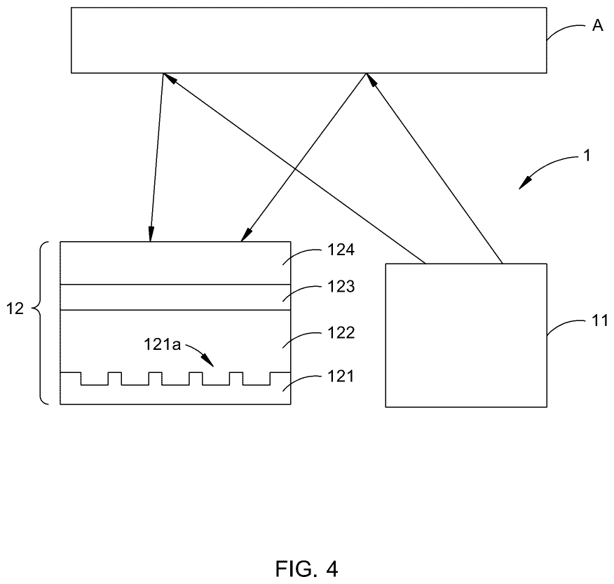

To settle this issue, please refer to FIG. 4, which is a schematic diagram of the structure of the light sensor 1 according to the first embodiment of the present application, comprising a light emitting component 11 and a light receiving component 12. The light emitting component 11 is typically made using a light-emitting diode (LED) or a laser diode, such as an Edge Emitting Laser (EEL) or a Vertical Cavity Surface Emitting Laser (VCSEL), to emit a light signal.

The light receiving component 12 may be integrated onto an integrated circuit chip (hereinafter referred to as the chip), which may also include control circuits to control the operation of the light emitting component 11 or the light receiving component 12, as well as to process the signals generated. However, in other embodiments, an external control circuit may also control and process signals for the light emitting component 11 or the light receiving component 12, where the control circuits may be located in an external system (such as a mobile communication device or wearable device). The present application is not limited to this configuration; therefore, only the part of the light receiving component 12 serving as the light-receiving surface is shown in the diagram.

The light receiving component 12, as part of the light-receiving surface, may be made using photodiodes and includes a light sensing layer 121 and an interlayer 122. The material of the light sensing layer 121 may be silicon or silicon-germanium (SiGe), among others. The interlayer 122 is disposed above the light sensing layer 121 in a vertical direction as shown in the diagram. The interlayer 122 may have a thickness T greater than 6 um in the vertical direction, and its material may have a different refractive index from the material of the light sensing layer 121. Generally, the interlayer 122 may be an interlayer dielectric (ILD), typically made of oxides or nitrides such as silicon dioxide, silicon nitride, or silicon oxynitride, to provide insulation and structural support.

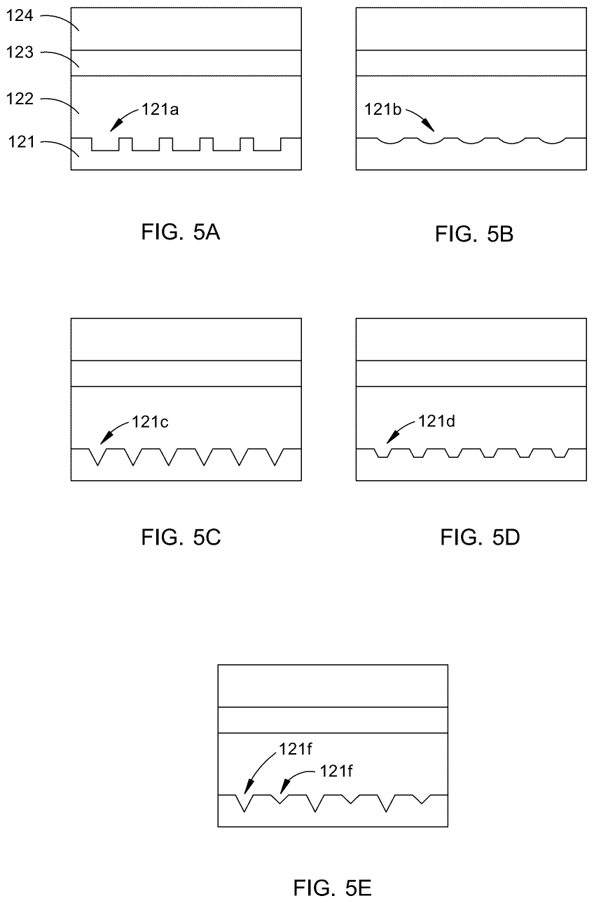

As above mentioned, due to the difference in refractive indices between the light sensing layer 121 and the interlayer 122 of the light receiving component 12, and considering the substantial thickness required for the interlayer 122 in current applications (e.g., about 8 um), to prevent constructive or destructive interference as light passes through the light sensing layer 121 and the interlayer 122, the first embodiment of the light sensor 1 in the present application places a plurality of microstructures 121a on the surface of the light sensing layer 121 facing the interlayer 122. According to the mainstream semiconductor processes used for making photodiodes, the microstructures 121a are preferably fabricated using photolithography etching techniques. However, if other suitable processes for fabricating microstructures on the light sensing layer 121 become available in the future, users may choose them as needed. Refer to FIG. 5A, in this embodiment, the microstructures 121a are rectangular grooves in cross-section. However, in practice, the first embodiment of the present application is not limited to this configuration.

Specifically, refer to FIG. 5B, in another implementation of the first embodiment of the present application, a plurality of microstructures 121b set on the surface of the light sensing layer 121 may be grooves with a circular arc cross-section. Refer to FIG. 5C, in another implementation of the first embodiment of the present application, a plurality of microstructures 121c set on the surface of the light sensing layer 121 may be grooves with a triangular cross-section. Refer to FIG. 5D, in another implementation of the first embodiment of the present application, a plurality of microstructures 121d set on the surface of the light sensing layer 121 may be grooves with a trapezoidal cross-section. In fact, the groove shapes listed in the above embodiments are merely exemplary, and other microstructure shapes that achieve the same effect are also within the scope of protection requested by the present application.

On the other hand, compared to the previous embodiments where a plurality of microstructures are almost identical and arranged in a repetitive pattern, refer to FIG. 5E, in another implementation of the first embodiment of the present application, the surface of the light sensing layer 121 may have two or more types of microstructures 121e, 121f. The two microstructures 121e, 121f mentioned may be grooves with triangular cross-sections but different sizes, as shown in the figure. Of course, the two microstructures 121e, 121f may also be grooves with two different cross-sectional shapes.

Furthermore, the photolithography etching technique has its process variations, thus there may be slight differences in the cross-sectional shapes of each microstructure; or the originally designed rectangular cross-section grooves may appear nearly circular in the final product, and the originally designed triangular cross-section grooves may appear nearly trapezoidal, as long as the final measured optical properties meet the requirements, they are still within the scope of protection requested by the present application. On the other hand, the light sensing layer 121 may have a width on a plane perpendicular to the aforementioned vertical direction, preferably greater than 20 um, to ensure sufficient space for setting the microstructures 121a˜121f mentioned.

In the first embodiment of the present application, the light sensor 1 is equipped with a plurality of microstructures 121a˜121f on the surface of the light sensing layer 121 facing the interlayer 122. These microstructures 121a˜121f may alter the direction of light passing through the interlayer 122 and the light sensing layer 121, thereby avoiding constructive or destructive interference. As a result, compared to the conventional technology where the interface between the light sensing layer 921 and the interlayer 922 is generally a flat surface, the interface of the light sensing layer 121 and the interlayer 122 in the first embodiment of the present application includes these microstructures 121a˜121f. This allows the light sensor 1 to reduce the ripple in transmittance when light emitted by the light emitting component 11 and reflected by object A enters the light receiving component 12 at various angles of incidence.

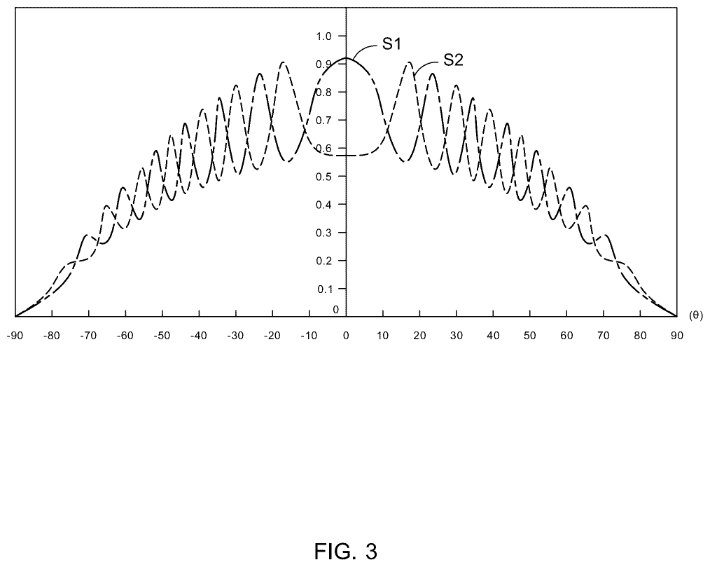

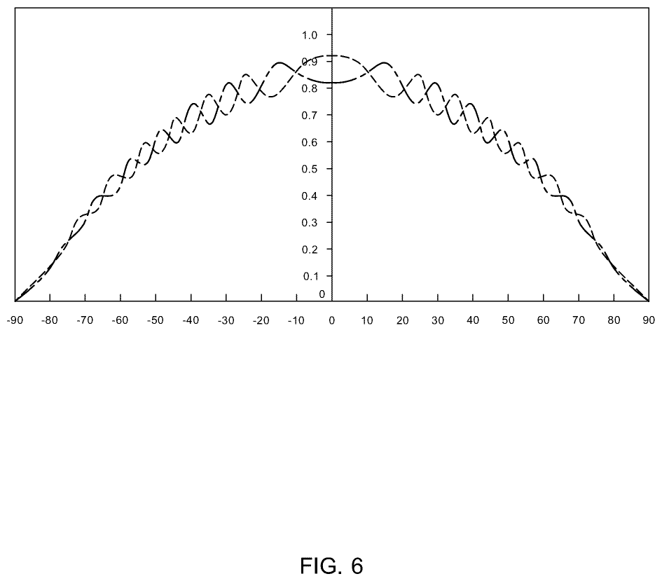

As shown in FIG. 3, the two samples S1, S2 of the conventional light sensor 9 actually have interlayers 922 with thicknesses of approximately 7.3 um and 7.9 um, respectively. Note that if the target thickness for the interlayers 922, 122 is 8 um, the variations in the manufacturing process during mass production will inevitably result in interlayers with thicknesses close to 8 um, thus resulting in products where the thicknesses of interlayers 922, 122 are approximately 7.3 um and 7.9 um. To highlight the effects achieved by the light sensor 1 in the first embodiment of the present application, optical simulation measurements were conducted on two samples S1′, S2′, each with interlayer 122 having thicknesses of approximately 7.3 um and 7.9 um respectively, and with a plurality of microstructures set on the surface of the light sensing layer 121 facing the interlayer 122. The results are shown in the transmittance distribution diagram in FIG. 6. It is first noted that for the sample S1′ with interlayer 122 at approximately 7.3 um, the transmittance at an incidence angle of 0° is in the valley of the ripple; however, for the sample S2′ with interlayer 122 at approximately 7.9 um, the transmittance at the same incidence angle of 0° is at the peak of the ripple, which is completely different from the performance shown in FIG. 3. Therefore, the light sensor 1 in the first embodiment of the present application, by setting a plurality of microstructures on the surface of the light sensing layer 121 facing the interlayer 122, may indeed alter the distribution of light transmittance at different angles of incidence.

More importantly, compared to the simulation results of the conventional technology in FIG. 3, the difference in transmittance between the two samples S1′ and S2′ has been significantly reduced. In other words, the light sensor 1 of the first embodiment of the present application, by setting a plurality of microstructures on the surface of the light sensing layer 121 towards the interlayer 122, effectively limits the optical performance differences between individual light sensor products, thereby solving issues of product calibration difficulty or poor yield, and significantly reducing the production cost of light sensors.

It should be noted that the light sensor 1 of the first embodiment of the present application avoids conditions that would form constructive or destructive interference between the light sensing layer 121 and the interlayer 122 of the light receiving component 12, to prevent uneven transmittance of light at different incident angles. To achieve this effect, users need to adjust the design of the microstructures set in the light sensing layer 121 according to the optical environment they are using. The conditions for interference formed by light of different wavelengths, affected by the refractive index of the medium, vary; therefore, to facilitate simulation measurements and complete the design of the microstructures in the light sensing layer 121, the light sensor 1 of the first embodiment of the present application is particularly suitable for cases where the light emitting component 11 is a single-wavelength light emitter, where the single-wavelength light emitter refers to a light emitter that emits light with the highest intensity at a specific wavelength (or within a specific wavelength range). For example, proximity sensors used in mobile phones typically operate within a wavelength range of 750-1600 nm, and the light emitting component 11 may be chosen as a single-wavelength light-emitting diode or laser diode that emits with the highest intensity at 940 nm (or within the range of 850-1000 nm). Consequently, users only need to design the microstructures of the light sensing layer 121 for light at the wavelength of 940 nm (or within the range of 850-1000 nm).

Notably, as shown in FIG. 4, the light receiving component 12, in addition to the light sensing layer 121 and the interlayer 122, may also include other layer structures. For example, the light receiving component 12 may further include a cover layer 123 above the interlayer 122 in the vertical direction, which may be a passivation layer made of materials such as silicon nitride or silicon oxide, to provide protection and blocking effects. In this embodiment, if the interlayer 122 is silicon dioxide and the cover layer 123 is silicon nitride, the difference in refractive indices of these materials may necessitate a plurality of microstructures in the light sensing layer 121 of the light receiving component 12 to avoid conditions that would lead to constructive or destructive interference.

Alternatively, the cover layer 123 may also include a filtering structure, typically consisting of a dielectric film, metal film, photoresist, or any combination thereof in a multilayer coating, primarily used to suppress noise outside the working wavelength range. For instance, when the working wavelength of the light emitting component 11 is 940 nm (or within the range of 850-1000 nm), light signals that significantly deviate from 940 nm may be considered noise and may be filtered out using the filtering structure. Similarly, when the interlayer 122 is silicon dioxide and the cover layer 123 consists of single or multiple coating layers, the difference in refractive indices of these materials may necessitate a plurality of microstructures in the light sensing layer 121 of the light receiving component 12 to prevent conditions that would lead to constructive or destructive interference.

Additionally, generally, the light receiving component 12 is covered by a packaging layer 124, which seals the light receiving component 12 and is typically made of a transparent film material. Similarly, due to the cumulative effect of refractive index differences between materials, the light receiving component 12 may require a plurality of microstructures in the light sensing layer 121 to avoid conditions that would lead to constructive or destructive interference.

In addition to the previously mentioned light sensing layer 121, interlayer 122, cover layer 123, and encapsulation layer 124, other layer structures that may be included in the light receiving component 12 cannot be exhaustively listed. For example, the light receiving component 12 may also include a lens to alter the distribution of the incident angle of light or the Field of View (FOV) of the light receiving component 12. Additionally, there may be layers such as an ink layer or a light guide layer above the light receiving component 12, which could lead to cumulative effects due to differences in refractive indices of different materials, thereby making the light receiving component 12 more reliant on a plurality of microstructures of the light sensing layer 121 to avoid conditions of constructive or destructive interference.

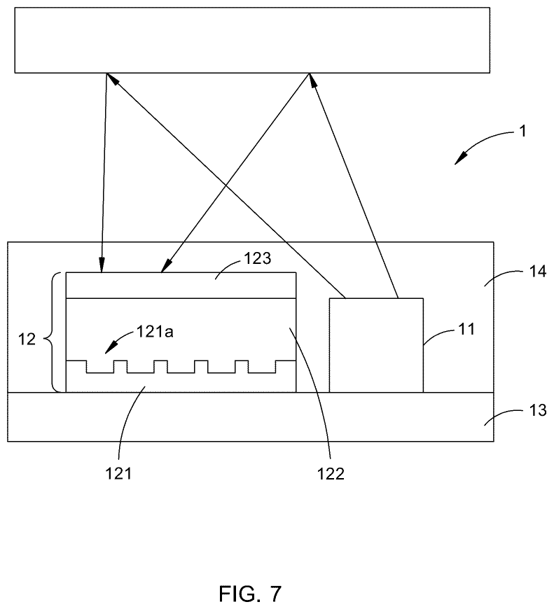

Please refer to FIG. 7, which illustrates the schematic of the light sensor 1 in the second embodiment of the present application. In the first embodiment, the light emitting component 11 and the light receiving component 12 of the light sensor 1 may be separately placed in an external system. However, as shown in the second embodiment, unlike the first embodiment, the light sensor 1 is typically integrated and packaged as a single component, where the light emitting component 11 and the light receiving component 12 are both placed on a substrate 13, and an encapsulation layer 14, generally made of a transparent film material, seals both the light emitting component 11 and the light receiving component 12.

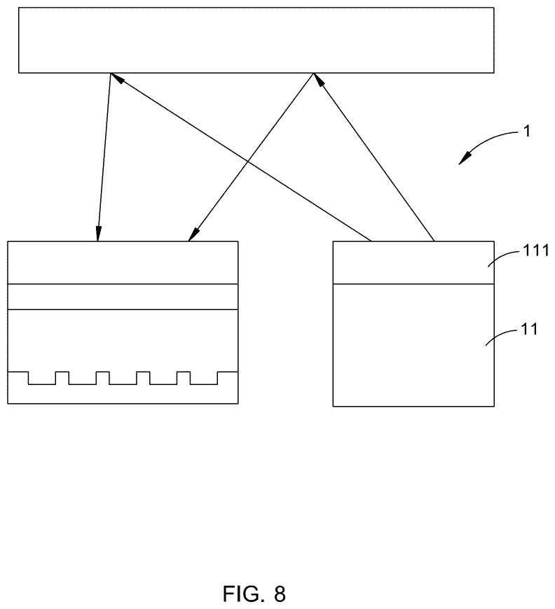

Please refer to FIG. 8, which illustrates the schematic of the light sensor 1 in the third embodiment of the present application. Although in the first embodiment, it was described that for facilitating the design of a plurality of microstructures of the light sensing layer 121, the light emitting component 11 is preferably a single-wavelength light emitter with the highest intensity at a specific wavelength (or within a specific wavelength range), it is practically challenging to obtain or manufacture a single-wavelength light emitter that fully meets the optical characteristics required. Therefore, as shown in the third embodiment, differing from the first embodiment, an optical filter 111 may be placed above the light emitting component 11 in the vertical direction, covering the light-emitting area of the light emitting component 11. This optical filter 111 may filter the light signals emitted by the light emitting component 11, ensuring they have the highest intensity at a specific wavelength (or within a specific wavelength range).

It should be noted that when the cover layer 123 includes a filtering structure, this filtering structure is preferably designed in conjunction with the optical filter 111, thereby allowing the light emitting component 11 to emit light of a specific wavelength (or range of wavelengths) as much as possible, and only allowing light of that specific wavelength (or range of wavelengths) to enter the light receiving component 12. This ensures that the light receiving component 12, when sensing light reflected by object A, maximally avoids uneven transmittance of light at different incident angles.

In summary, the embodiments of the light sensor of the present application involve setting a plurality of microstructures in the light sensing layer of the light receiving component to change the direction of light passing through the various layers of the light emitting component, thereby avoiding constructive or destructive interference. This allows for a reduction in ripple in transmittance when light emitted by the light emitting component enters the light receiving component at different incident angles after being reflected by an object, effectively limiting optical performance variations between individual light sensor products, addressing issues of difficult calibration or poor yield, and significantly reducing the production costs of light sensors.

The above descriptions are merely preferred embodiments of the present application, and all equivalent variations and modifications within the scope of the patent application for the present application are intended to be within the scope of the present application.

1. A light sensor, comprising:
a light emitting component, configured for emitting a light signal; and
a light receiving component, comprising a light sensing layer and an interlayer, the interlayer disposed above the light sensing layer along a vertical direction, the light sensing layer including a plurality of microstructures set on the surface of the light sensing layer facing the interlayer;
wherein the light signal reflected by an object enters the light receiving component and is received by the light sensing layer after passing through the interlayer.

2. The light sensor of claim 1, wherein the material of the interlayer has a different refractive index from the material of the light sensing layer.

3. The light sensor of claim 1, wherein the thickness of the interlayer in the vertical direction is greater than 6 um.

4. The light sensor of claim 1, wherein the light emitting component is a light emitter with the highest intensity at a specific wavelength range.

5. The light sensor of claim 4, wherein an optical filter is disposed above the emitting component in the vertical direction, which filters the light signal emitted by the emitting component, providing maximum intensity within a specific wavelength range.

6. The light sensor of claim 1, wherein the receiving component includes an additional covering layer above the interlayer in the vertical direction.

7. The light sensor of claim 6, wherein the covering layer is a passivation layer, and the material of the interlayer has a different refractive index from the material of the passivation layer.

8. The light sensor of claim 6, wherein the covering layer includes a filtering structure.

9. The light sensor of claim 1, wherein the receiving component is covered by a packaging layer made of transparent film material.

10. The light sensor of claim 1, which further includes a substrate, on which both the emitting component and the receiving component are mounted.

11. The light sensor of claim 10, wherein both the emitting component and the receiving component are covered by a packaging layer made of transparent film material.

12. The light sensor of claim 1, wherein the microstructures are grooves with cross-sections in the shapes of rectangles, arcs, triangles, or trapezoids.

13. The light sensor of claim 1, wherein the microstructures include grooves of two different cross-sectional sizes.
